(19) United States
(12) Patent Application Publication
(10) Pub. No.: US 2020/0251171 A1
(43) Pub. Date: Aug. 6, 2020

(54) Programmable Memory Cell Using an Internal Parasitic Diode for Programming the Programmable Memory Cell

(71) Applicant: AGI CORPORATION, Hsinchu (TW)

(72) Inventors: SHIH-HSIU CHEN, HSINCHU (TW); WEI-FAN WU, HSINCHU (TW); HSUAN-CHI SU, HSINCHU (TW); WEI HUAN CHEN, HSINCHU (TW); CHING-HSIANG LIN, HSINCHU (TW); YUNG-CHIEN LEE, HSINCHU (TW); SHUI-SHOU WANG, HSINCHU (TW); WEN-HUA YU, HSINCHU (TW)

(21) Appl. No.: 16/423,174

(22) Filed: May 28, 2019

Related U.S. Application Data
(60) Provisional application No. 62/799,759, filed on Feb. 1, 2019.

(51) Int. Cl. G11C 17/18; H01L 27/112; H01L 23/525; H01L 29/10; H01L 23/528; G11C 17/16

(52) U.S. Cl. CPC G11C 17/18; H01L 27/11206; H01L 23/5256; G11C 17/16; H01L 23/528; H01L 23/5252; H01L 29/1095

(57) ABSTRACT

A circuit to program a programmable memory cell, such as an OTP (One-Time-Programmable) memory cell, by using by using an additional conductive path from a bit line (or a source line) to a source line (or a bit line) of the OTP (One-Time-Programmable) memory cell via an internal parasitic diode for programming the OTP memory cell.

### CROSS-REFERENCES TO RELATED APPLICATIONS

This application claims the benefit of U.S. Provisional Patent Application No. 62/799,759 filed on Feb. 1, 2019, which is hereby incorporated by reference herein and made a part of the specification.

### BACKGROUND OF THE INVENTION

### I. Field of the Invention

The invention relates to a programmable memory cell and, in particular, but not exclusively, to a programmable memory cell with feedback signal for programming the programmable memory cell. The invention relates to a programmable memory cell and, in particular, but not exclusively, to a programmable memory cell using an internal diode thereof for programming the programmable memory cell.

### II. Description of the Prior Art

Conventional methods to program a programmable memory cell such as an OTP (One-Time-Programmable) memory cell utilize a current source (or voltage source) to generate a constant current (or voltage) to a bit line of the OTP memory cell. In such methods, there is no feedback signal from the OTP memory cell to indicate the current status of the fuse element inside the OTP memory cell. As a result, the fuse element of the OTP memory cell can potentially explode and damage the circuits surrounding the fuse element when the fuse element is overheated for a certain amount of time.

In another aspect, conventional methods to program a programmable memory cell such as an OTP (One-Time-Programmable) memory cell by applying a current to a bit line of the OTP memory cell, wherein only one conductive path from the bit line to a source line of an OTP (One-Time-Programmable) memory cell is used to program the OTP memory cell. In such methods, it takes longer time to program the OTP memory cell since there is only one conductive path from the bit line to a source line of an OTP (One-Time-Programmable) memory cell. Also, it requires larger MOSFET to provide enough current to program OTP (Fuse) cell.

Therefore, a better solution is needed to resolve the above-mentioned issue.

### SUMMARY OF THE INVENTION

One objective of the present invention is to provide a circuit to program an OTP (One-Time-Programmable) memory cell by using at least two conductive paths comprising an internal parasitic diode for programming the OTP memory cell.

One objective of the present invention is to provide a circuit to program a programmable resistive memory cell by using at least two conductive paths comprising an internal parasitic diode for programming the programmable resistive memory cell.

In one embodiment of the present invention, a structure comprising an OTP memory cell is disclosed, wherein the structure comprises: a P-type substrate, wherein an N-Well region is formed in the P-type substrate, wherein a first P+ region, a second P+ region, a third N+ region are formed in the N-Well region and a gate is formed over the N-Well region so that the first P+ region and the second P+ region and the gate form a P-channel field-effect transistor (FET); and a first fuse element, disposed on the P-type substrate, wherein one terminal of the first fuse element is electrically connected to the first P+ region so as to form the OTP memory cell, wherein the other terminal of the first fuse element is electrically connected to a bit line of the OTP memory cell, and the second P+ region and the third N+ region are electrically connected to a source line (SL) of the OTP memory cell, wherein the source line (SL) of the OTP memory cell is electrically connected to a ground when programming the OTP memory cell so as to enable a current to flow from the first P+ region to the third N+ region via a parasitic diode in the N-Well region, and the source line (SL) of the OTP memory cell is electrically connected to a power supply when performing a read operation on the OTP memory cell.

In one embodiment of the present invention, a structure comprising an OTP memory cell is disclosed, wherein the structure comprises: a N-type substrate, wherein a P-Well region is formed in the N-type substrate, wherein a first N+ region, a second N+ region, a third P+ region are formed in the P-Well region and a gate is formed over the P-Well region so that the first N+ region and the second N+ region and the gate form a N-Channel field-effect transistor (FET); and a first fuse element, disposed on the N-type substrate, wherein one terminal of the first fuse element is electrically connected to the first N+ region so as to form the OTP memory cell, wherein the other terminal of the first fuse element is electrically connected to a bit line of the OTP memory cell, and the second N+ region and the third P+ region are electrically connected to a source line (SL) of the OTP memory cell, wherein the source line (SL) of the OTP memory cell is electrically connected to a power supply when programming the OTP memory cell so as to enable a current to flow from the third P+ region to the first N+ region via a parasitic diode in the P-Well region, and the source line (SL) of the OTP memory cell is electrically connected to a ground when performing a read operation on the OTP memory cell.

In one embodiment of the present invention, a structure comprising a programmable resistive memory cell, said structure comprising: a P-type substrate, wherein an N-Well region is formed in the P-type substrate, wherein a first P+ region, a second P+ region, a third N+ region are formed in the N-Well region and a gate is formed over the N-Well region so that the first P+ region and the second P+ region and the gate form a P-channel field-effect transistor (FET); and a first programmable resistive element, disposed on the P-type substrate, wherein one terminal of the first programmable resistive element is electrically connected to the first P+ region so as to form the programmable resistive memory cell, wherein the other terminal of the first programmable resistive element is electrically connected to a bit line of the programmable resistive memory cell, and the second P+ region and the third N+ region are electrically connected to a source line (SL) of the programmable resistive memory cell, wherein the source line (SL) of the programmable resistive memory cell is electrically connected to a ground when programming the programmable resistive memory cell so as to enable a current to flow from the first P+ region to the third N+ region via a parasitic diode in the N-Well region, and the source line (SL) of the programmable resistive memory cell is electrically connected to a power supply when performing a read operation on the programmable resistive memory cell.

In one embodiment of the present invention, a structure comprising a programmable resistive memory cell, said structure comprising: a N-type substrate, wherein a P-Well region is formed in the N-type substrate, wherein a first N+ region, a second N+ region, a third P+ region are formed in the P-Well region and a gate is formed over the P-Well region so that the first N+ region and the second N+ region and the gate form a N-Channel field-effect transistor (FET); and a first programmable resistive element, disposed on the N-type substrate, wherein one terminal of the first programmable resistive element is electrically connected to the first N+ region so as to form the programmable resistive memory cell, wherein the other terminal of the first programmable resistive element is electrically connected to a bit line of the programmable resistive memory cell, and the second N+ region and the third P+ region are electrically connected to a source line (SL) of the programmable resistive memory cell, wherein the source line (SL) of the programmable resistive memory cell is electrically connected to a power supply when programming the programmable resistive memory cell so as to enable a current to flow from the third P+ region to the first N+ region via a parasitic diode in the P-Well region, and the source line (SL) of the programmable resistive memory cell is electrically connected to a ground when performing a read operation on the programmable resistive memory cell.

The detailed technology and above preferred embodiments implemented for the present invention are described in the following paragraphs accompanying the appended drawings for people skilled in this field to well appreciate the features of the claimed invention.

### BRIEF DESCRIPTION OF DRAWINGS

The foregoing aspects and many of the accompanying advantages of this invention will become more readily appreciated as the same becomes better understood by reference to the following detailed description when taken in conjunction with the accompanying drawings, wherein:

FIG. 1A illustrates a circuit comprising an OTP memory cell with a feedback voltage for programming the OTP memory cell in accordance with one embodiment of the present invention;

FIG. 1B illustrates a circuit comprising an OTP memory cell with a feedback current for programming the OTP memory cell in accordance with one embodiment of the present invention;

FIG. 2A illustrates a circuit comprising a programmable resistive memory cell with a feedback voltage for programming the programmable resistive memory cell in accordance with one embodiment of the present invention; and

FIG. 2B illustrates a circuit comprising a programmable resistive memory cell with a feedback current for programming the programmable resistive memory cell in accordance with one embodiment of the present invention;

FIG. 3 illustrates a structure comprising an OTP memory cell in accordance with one embodiment of the present invention;

FIG. 4 illustrates a structure comprising an OTP memory cell in accordance with one embodiment of the present invention;

FIG. 5 illustrates a structure comprising a programmable resistive memory cell in accordance with one embodiment of the present invention;

FIG. 6 illustrates a structure comprising a programmable resistive memory cell in accordance with one embodiment of the present invention; and

FIG. 7 illustrates a switching circuit for conditioning the voltage of a source line of a programmable memory cell in accordance with one embodiment of the present invention;

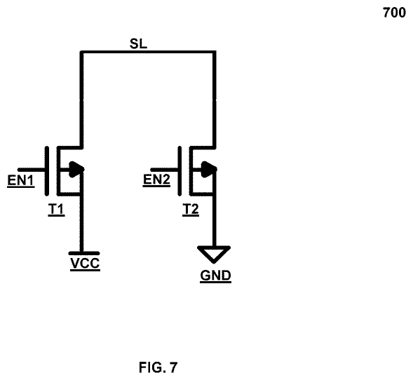

### DETAILED DESCRIPTION OF EMBODIMENT

The detailed explanation of the present invention is described as following. The described preferred embodiments are presented for purposes of illustrations and description, and they are not intended to limit the scope of the present invention.

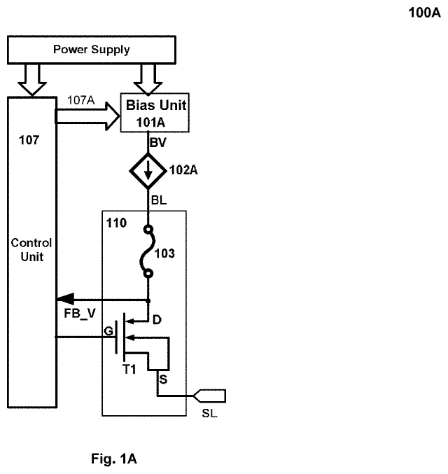

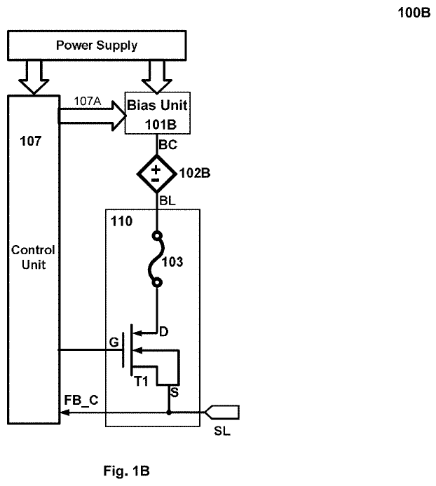

FIG. 1A illustrates a circuit comprising an OTP memory cell with a feedback voltage for programming the OTP memory cell in accordance with one embodiment of the present invention. As shown in FIG. 1A, the circuit comprises an OTP memory cell 110 wherein OTP memory cell 110 comprises a fuse element 103 and a field-effect transistor (FET) T1, wherein a bit line BL of the OTP memory cell 110 and the channel path of the field-effect transistor (FET) T1 are electrically connected via the fuse element 103; a bias unit 101A, for supplying a bias voltage BV to a current source 101A that is electrically coupled to the bit line BL of the OTP memory cell 110; and a control unit 107, for receiving a feedback voltage FB_V capable of indicating a voltage change across the fuse element 103, wherein when programming the OTP memory cell 110, the bias voltage BV is adjusted according to the received feedback voltage FB_V. The received feedback voltage FB_V can indicate a voltage change across the fuse element 103 while programming the OTP memory cell 110 due to the resistance of the fuse element 103 will vary while programming the OTP memory cell 110.

In one embodiment, the fuse element 103 is an e-fuse (electrical fuse).

In one embodiment, the fuse element 103 is an antifuse.

In one embodiment, the OTP memory cell is formed by a CMOS process.

In one embodiment, the field-effect transistor (FET) T1 is an N-channel field-effect transistor, wherein the drain terminal D of the field-effect transistor (FET) T1 is coupled to the fuse element 103, the drain terminal S of the field-effect transistor (FET) T1 is coupled to the source line SL of the OTP memory cell 110, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a voltage comparator to determine whether the feedback voltage FB_V has reached a predetermined threshold voltage, and the control unit 107 decreases or cuts off the bias voltage BV to the current source 101A by using at least one control signal 107A.

In one embodiment, the bias unit 101A comprises a digital to analog converter for generating the bias voltage BV.

In one embodiment, the bias unit 101A comprises a plurality of reference voltages that can be selected for generating the bias voltage BV.

In one embodiment, the control unit 107 comprises an analog-to-digital converter (ADC) to convert the feedback voltage FB_V to binary bits, wherein the control unit 107 decreases or cuts off the bias voltage BV by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias voltage BV of the bias unit 101A.

In one embodiment, the control unit 107 can be entirely implemented in hardware.

FIG. 1B illustrates a circuit comprising an OTP memory cell with a feedback voltage for programming the OTP memory cell in accordance with one embodiment of the present invention. As shown in FIG. 1B, the circuit comprises an OTP memory cell 110 wherein OTP memory cell 110 comprises a fuse element 103 and a field-effect transistor (FET) T1, wherein a bit line BL of the OTP memory cell 110 and the channel path of the field-effect transistor (FET) T1 are electrically connected via the fuse element 103; a bias unit 101B, for supplying a bias current BC to a voltage source 101B that is electrically coupled to the bit line BL of the OTP memory cell 110; and a control unit 107, for receiving a feedback current FB_C capable of indicating a voltage change across the fuse element 103, wherein when programming the OTP memory cell 110, the bias current BC is adjusted according to the received feedback current FB_C.

In one embodiment, the bias unit 101B comprises a digital to analog converter for generating the bias current BC.

In one embodiment, the bias unit 101B comprises a plurality of current sources that can be selected for generating the current BC.

In one embodiment, the fuse element 103 is an e-fuse (electrical fuse).

In one embodiment, the fuse element 103 is an antifuse.

In one embodiment, the OTP memory cell is formed by a CMOS process.

In one embodiment, the field-effect transistor (FET) T1 is an N-channel field-effect transistor, wherein the drain terminal D of the field-effect transistor (FET) T1 is coupled to the fuse element 103, the drain terminal S of the field-effect transistor (FET) T1 is coupled to the source line SL of the OTP memory cell 110, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a current meter to determine whether the feedback current FB_C has reached a predetermined threshold current, and the control unit 107 decreases or cuts off the bias current BC by using at least one control signal 107A, when the predetermined threshold current is reached.

In one embodiment, the control unit 107 comprises current-to-voltage converter to convert the feedback current FB_C to a corresponding voltage, wherein the control unit 107 decreases or cuts off the bias voltage BV when said corresponding voltage reaches a predetermined threshold voltage.

In one embodiment, the control unit 107 comprises an analog-to-digital converter (ADC) to convert said corresponding voltage to binary bits, wherein the control unit 107 decreases or cuts off the bias current BC by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias current BC of the bias unit 101B.

In one embodiment, the control unit 107 can be entirely implemented in hardware.

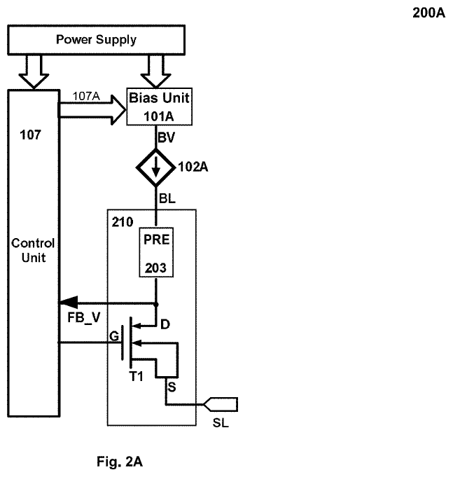

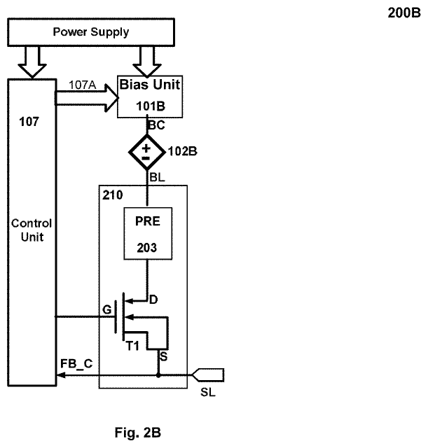

FIG. 2A illustrates a circuit comprising programmable resistive memory cell with a feedback voltage for programming the OTP memory cell in accordance with one embodiment of the present invention. As shown in FIG. 2A, the circuit comprises: a programmable resistive memory cell 210, wherein the programmable resistive memory cell 210 comprises a programmable resistive element (PRE) 203 and a field-effect transistor (FET) T1, wherein a bit line BL of the programmable resistive memory cell 210 and the channel path of the field-effect transistor (FET) T1 are electrically connected via the programmable resistive element 203; a bias unit 101A, for supplying a bias voltage BV to a current source 101A that is electrically coupled to the bit line BL of the programmable resistive memory cell 210; and a control unit 107, for receiving a feedback voltage FB_V capable of indicating a voltage change across the programmable resistive element 203, wherein when programming the programmable resistive memory cell 210, the bias voltage BV is adjusted according to the received feedback voltage FB_V.

In one embodiment, the field-effect transistor (FET) T1 is an N-channel field-effect transistor, wherein the drain terminal D of the field-effect transistor (FET) T1 is coupled to the programmable resistive element 203, the drain terminal S of the field-effect transistor (FET) T1 is coupled to the source line SL of the programmable resistive memory cell 210, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a voltage comparator to determine whether the feedback voltage FB_V has reached a predetermined threshold voltage, and the control unit 107 decreases or cuts off the bias voltage BV to the current source 101A by using at least one control signal 107A.

In one embodiment, the control unit 107 comprises an analog-to-digital converter (ADC) to convert the feedback voltage FB_V to binary bits, wherein the control unit 107 decreases or cuts off the bias voltage BV by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias voltage BV of the bias unit 101A.

In one embodiment, the control unit 107 can be entirely implemented in hardware.

FIG. 2B illustrates a circuit comprising programmable resistive memory cell with a feedback voltage for programming the OTP memory cell in accordance with one embodiment of the present invention. As shown in FIG. 2B, the circuit comprises: a programmable resistive memory cell 210, wherein the programmable resistive memory cell 210 comprises a programmable resistive element (PRE) 203 and a field-effect transistor (FET) T1, wherein a bit line BL of the programmable resistive memory cell 210 and the channel path of the field-effect transistor (FET) T1 are electrically connected via the programmable resistive element 203; a bias unit 101B, for supplying a bias current BC to a voltage source 102B that is electrically coupled to the bit line BL of the programmable resistive memory cell 210; and a control unit 107, for receiving a feedback current FB_C capable of indicating a voltage change across the programmable resistive element 203, wherein when programming the programmable resistive memory cell 210, the bias current BC is adjusted according to the received feedback current FB_C.

In one embodiment, the field-effect transistor (FET) T1 is an N-channel field-effect transistor, wherein the drain terminal D of the field-effect transistor (FET) T1 is coupled to the programmable resistive element 203, the drain terminal S of the field-effect transistor (FET) T1 is coupled to the source line SL of the programmable resistive memory cell 210, and the gate terminal G of the field-effect transistor (FET) T1 is coupled to the control unit 107.

In one embodiment, the field-effect transistor (FET) T1 can be a P-channel field-effect transistor.

In one embodiment, the control unit 107 comprises a current meter to determine whether the feedback current FB_C has reached a predetermined threshold current, and the control unit 107 decreases or cuts off the bias current BC by using the at least one control signal 107A.

In one embodiment, the control unit 107 comprises a current-to-voltage converter to convert the feedback current FB_C to a corresponding voltage, wherein the control unit 107 decreases or cuts off the bias voltage BV when said corresponding voltage reaches a predetermined threshold voltage.

In one embodiment, the control unit 107 comprises an analog-to-digital converter (ADC) to convert said corresponding voltage to binary bits, wherein the control unit 107 decreases or cuts off the bias current BC by using at least one control signal 107A, when the binary bits has reached a predetermined threshold value.

In one embodiment, the control unit 107 comprises a microprocessor to control or manage the analog-to-digital converter (ADC). In one embodiment, the control unit 107 comprises a mapping table, wherein the binary bits are mapped to a corresponding bias current BC of the bias unit 102. In one embodiment, the control unit 107 can be entirely implemented in hardware.

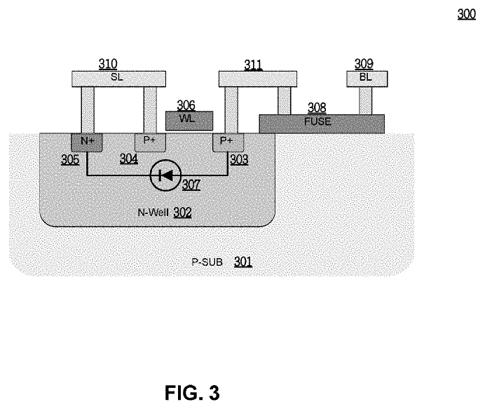

FIG. 3 illustrates a schematic illustrating a structure comprising an OTP memory cell 300 in accordance with one embodiment of present invention, wherein the structure comprises: a P-type substrate 301, wherein an N-Well region 302 is formed in the P-type substrate, wherein a first P+ region 303, a second P+ region 304, a third N+ region 305 are formed in the N-Well region 302 and a gate 306 is formed over the N-Well region 302 so that the first P+ region 303 and the second P+ region 304 and the gate 306 form a P-channel field-effect transistor (FET); and a first fuse element 308, disposed on the P-type substrate 301, wherein one terminal of the first fuse element 308 is electrically connected to the first P+ region 303 so as to form the OTP memory cell 300, wherein the other terminal of the first fuse element 308 is electrically connected to a bit line 309 of the OTP memory cell 300, and the second P+ region 304 and the third N+ region 305 are electrically connected to a source line (SL) 310 of the OTP memory cell 300, wherein the source line (SL) 310 of the OTP memory cell 300 is electrically connected to a ground when programming the OTP memory cell 300 so as to enable a current to flow from the first P+ region 303 to the third N+ region 305 via a parasitic diode 306 in the N-Well region 302, and the source line (SL) 310 of the OTP memory cell 300 is electrically connected to a power supply when performing a read operation on the OTP memory cell 300.

In one embodiment, the structure comprises a switch circuit 700, wherein the source line (SL) 310 of the OTP memory cell 300 is electrically connected to a first switch transistor T1 and a second switch transistor T2, wherein when programming the OTP memory cell 300, the control signal EN2 is active so as to enable a current to flow from the bit line 309 to the source line 310 being electrically connected a ground GND via the parasitic diode 306; wherein when reading the OTP memory cell 100, the control signal EN1 is active so as to electrically connect the source line 310 to a voltage supply VCC for allowing a current to flow from the source line 310 to the bit line 309.

In one embodiment, the fuse element is a fuse.

In one embodiment, the fuse element is an antifuse.

In one embodiment, the OTP memory cell is made by a CMOS process.

In one embodiment, the OTP memory cell 300 is the OTP memory cell 110 in FIG. 1A, wherein the node 311 is used as a feedback voltage shown as FB_V in FIG. 1A, wherein the bit line 309 of the OTP memory cell 300 receives a current for programming the OTP memory cell 300, wherein the amount of the current can be adjusted according to the feedback voltage generated at the node 311 of the OTP memory cell 300.

In one embodiment, the OTP memory cell 300 is the OTP memory cell 110 in FIG. 1B, wherein the bit line 309 of the OTP memory cell 300 receives a voltage for programming the OTP memory cell 300, wherein the level of the voltage can be adjusted according to a feedback current from source line 310 of the OTP memory cell 300.

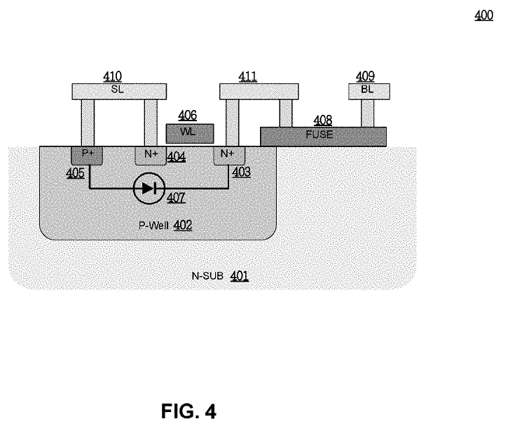

FIG. 4 illustrates a schematic illustrating a structure comprising an OTP memory cell 400 in accordance with one embodiment of present invention, wherein the structure comprises: a N-type substrate 401, wherein an P-Well region 402 is formed in the N-type substrate 401, wherein a first N+ region 403, a second N+ region 404, a third P+ region 405 are formed in the P-Well region 402 and a gate 406 is formed over the P-Well region 402 so that the first N+ region 403 and the second N+ region 404 and the gate 406 form a N-channel field-effect transistor (FET); and a first fuse element 408, disposed on the N-type substrate 401, wherein one terminal of the first fuse element 408 is electrically connected to the first N+ region 403 so as to form the OTP memory cell 400, wherein the other terminal of the first fuse element 408 is electrically connected to a bit line 409 of the OTP memory cell 400, and the second N+ region 404 and the third P+ region 405 are electrically connected to a source line (SL) 410 of the OTP memory cell 400, wherein the source line (SL) 410 of the OTP memory cell 400 is electrically connected to a power supply when programming the OTP memory cell 400 so as to enable a current to flow from the third P+ region 405 to the first N+ region 403 via a parasitic diode 406 in the P-Well region 402, and the source line (SL) 410 of the OTP memory cell 400 is electrically connected to a ground when performing a read operation on the OTP memory cell 400.

In one embodiment, the structure comprises a switch circuit 700, wherein the source line (SL) 410 of the OTP memory cell 400 is electrically connected to a first switch transistor T1 and a second switch transistor T2, wherein when programming the OTP memory cell 400, the control signal EN1 is active so as to electrically connect the source line 410 to a voltage supply VCC for allowing a current to flow from the source line 410 to the bit line 409 via the parasitic diode 406; wherein when reading the OTP memory cell 400, the control signal EN2 is active so as to electrically connect the source line 410 to a ground GND for allowing a current to flow from the bit line 409 to the source line 410.

In one embodiment, the fuse element is a fuse.

In one embodiment, the fuse element is an antifuse.

In one embodiment, the OTP memory cell is made by a CMOS process.

In one embodiment, the OTP memory cell 400 is the OTP memory cell 110 in FIG. 1A, wherein the node 411 is used as a feedback voltage shown as FB_V in FIG. 1A, wherein the source line 410 of the OTP memory cell 400 receives a current for programming the OTP memory cell 400, wherein the amount of the current can be adjusted according to the feedback voltage from the node 411 of the OTP memory cell 400.

In one embodiment, the OTP memory cell 400 is the OTP memory cell 110 in FIG. 1B, wherein the source line 410 of the OTP memory cell 400 receives a voltage for programming the OTP memory cell 400, wherein the level of the voltage can be adjusted according to a feedback current from bit line 409 of the OTP memory cell 400.

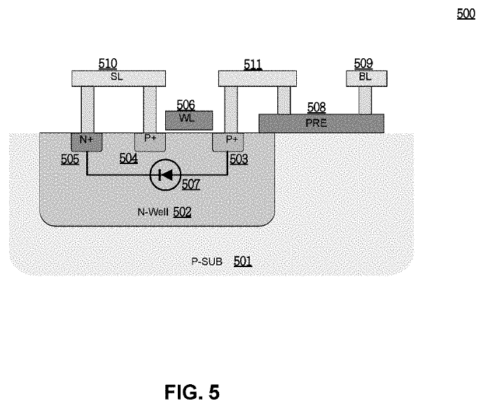

FIG. 5 illustrates a schematic illustrating a structure comprising a programmable resistive memory cell 500 in accordance with one embodiment of present invention, wherein the structure comprises: a P-type substrate 501, wherein an N-Well region 502 is formed in the P-type substrate 501, wherein a first P+ region 503, a second P+ region 504, a third N+ region 505 are formed in the N-Well region 502 and a gate 506 is formed over the N-Well region 502 so that the first P+ region 503 and the second P+ region 504 and the gate 506 form a P-channel field-effect transistor (FET); and a first programmable resistive element (PRE) 508, disposed on the P-type substrate 501, wherein one terminal of the programmable resistive element 508 is electrically connected to the first P+ region 503 so as to form the programmable resistive memory cell 500, wherein the other terminal of the first programmable resistive element 508 is electrically connected to a bit line of the programmable resistive memory cell 500, and the second P+ region 504 and the third N+ region 505 are electrically connected to a source line (SL) 510 of the programmable resistive memory cell 500, wherein the source line (SL) 510 of the programmable resistive memory cell 500 is electrically connected to a ground when programming the programmable resistive memory cell 500 so as to enable a current to flow from the first P+ region 503 to the third N+ region 505 via a parasitic diode 506 in the N-Well region 502, and the source line (SL) 510 of the programmable resistive memory cell 500 is electrically connected to a power supply when performing a read operation on the programmable resistive memory cell 500.

In one embodiment, the structure comprises a switch circuit 700, wherein the source line (SL) 510 of the programmable resistive memory cell 500 is electrically connected to a first switch transistor T1 and a second switch transistor T2, wherein when programming the programmable resistive memory cell 500, the control signal EN2 is active so as to enable a current to flow from the bit line 509 to the source line 510 being connected a ground GND via the parasitic diode 506; wherein when reading the programmable resistive memory cell 500, the control signal EN1 is active so as to electrically connect the source line 510 to a voltage supply VCC for allowing a current to flow from the source line 510 to the bit line 509.

In one embodiment, the programmable resistive memory cell 500 is made by a CMOS process.

In one embodiment, the programmable resistive memory cell 500 is the programmable resistive memory cell 210 in FIG. 2A, wherein the node 511 is used as a feedback voltage shown as FB_V in FIG. 2A, wherein the bit line 509 of the programmable resistive memory cell 500 receives a current for programming the programmable resistive memory cell 500, wherein the amount of the current can be adjusted according to the feedback voltage from the node 511 of the programmable resistive memory cell 500.

In one embodiment, the programmable resistive memory cell 500 is the programmable resistive memory cell 210 in FIG. 2B, wherein the bit line of the programmable resistive memory cell 500 receives a voltage for programming the programmable resistive memory cell 500, wherein the level of the voltage can be adjusted according to a feedback current from the source line 510 of the programmable resistive memory cell 500.

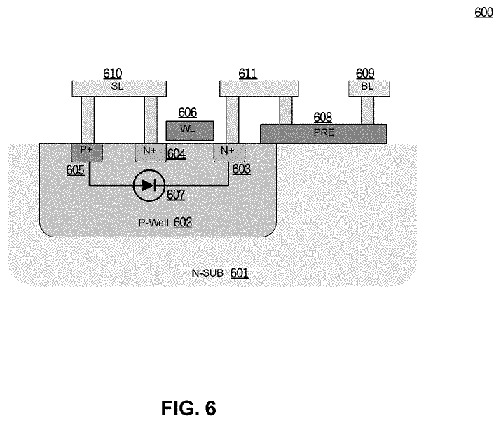

FIG. 6 illustrates a schematic illustrating a structure comprising a programmable resistive memory cell 600 in accordance with one embodiment of present invention, wherein the structure comprises: a N-type substrate 601, wherein an P-Well region 602 is formed in the N-type substrate 601, wherein a first N+ region 603, a second N+ region 604, a third P+ region 605 are formed in the P-Well region 602 and a gate 606 is formed over the P-Well region 602 so that the first N+ region 603 and the second N+ region 604 and the gate 606 form a N-channel field-effect transistor (FET); and a first programmable resistive element 608, disposed on the N-type substrate 601, wherein one terminal of the first programmable resistive element 608 is electrically connected to the first N+ region 603 so as to form the programmable resistive memory cell 600, wherein the other terminal of the first programmable resistive element 608 is electrically connected to a bit line 609 of the programmable resistive memory cell 600, and the second N+ region 604 and the third P+ region 605 are electrically connected to a source line (SL) 610 of the programmable resistive memory cell 600, wherein the source line (SL) 610 of the programmable resistive memory cell 600 is electrically connected to a power supply when programming the programmable resistive memory cell 600 so as to enable a current to flow from the third P+ region 605 to the first N+ region 603 via a parasitic diode 606 in the P-Well region 602, and the source line (SL) 610 of the programmable resistive memory cell 600 is electrically connected to a ground when performing a read operation on the programmable resistive memory cell 600.

In one embodiment, the structure comprises a switch circuit 700, wherein the source line (SL) 610 of the programmable resistive memory cell 600 is electrically connected to a first switch transistor T1 and a second switch transistor T2, wherein when programming the programmable resistive memory cell 600, the control signal EN1 is active so as to electrically connect the source line 610 to a voltage supply VCC for allowing a current to flow from the source line 610 to the bit line 609 via the parasitic diode 606; wherein when reading the programmable resistive memory cell 600, the control signal EN2 is active so as to electrically connect the source line 610 to a ground GND for allowing a current to flow from the bit line 609 to the source line 610.

In one embodiment, the programmable resistive memory cell 600 is made by a CMOS process.

In one embodiment, the programmable resistive memory cell 600 is the programmable resistive memory cell 210 in FIG. 2A, wherein the node 611 is used as a feedback voltage shown as FB_V in FIG. 2A, wherein the source line 610 of the programmable resistive memory cell 600 receives a current for programming the programmable resistive memory cell 600, wherein the amount of the current can be adjusted according to the feedback voltage from the node 611 of the programmable resistive memory cell 600.

In one embodiment, the programmable resistive memory cell 600 is the OTP memory cell 210 in FIG. 2B, wherein the source line 610 of the programmable resistive memory cell 600 receives a voltage for programming the programmable resistive memory cell 600, wherein the level of the voltage can be adjusted according to a feedback current from bit line 609 of the programmable resistive memory cell 600.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A structure comprising an OTP memory cell, said structure comprising:
a P-type substrate, wherein an N-Well region is formed in the P-type substrate, wherein a first P+ region, a second P+ region, a third N+ region are formed in the N-Well region and a gate is formed over the N-Well region so that the first P+ region and the second P+ region and the gate form a P-channel field-effect transistor (FET); and
a first fuse element, disposed on the P-type substrate, wherein one terminal of the first fuse element is electrically connected to the first P+ region so as to form the OTP memory cell, wherein the other terminal of the first fuse element is electrically connected to a bit line of the OTP memory cell, and the second P+ region and the third N+ region are electrically connected to a source line (SL) of the OTP memory cell, wherein the source line (SL) of the OTP memory cell is electrically connected to a ground when programming the OTP memory cell so as to enable a current to flow from the first P+ region to the third N+ region via a parasitic diode in the N-Well region, and the source line (SL) of the OTP memory cell is electrically connected to a power supply when performing a read operation on the OTP memory cell.

2. The circuit according to claim 1, wherein the fuse element is a fuse.

3. The circuit according to claim 1, wherein the fuse element is an antifuse.

4. The circuit according to claim 1, wherein the OTP memory cell is made by a CMOS process.

5. The circuit according to claim 1, wherein the bit line of the OTP memory cell receives a current for programming the OTP memory cell, wherein the amount of the current can be adjusted according to a feedback voltage from the OTP memory cell.

6. The circuit according to claim 1, wherein the bit line of the OTP memory cell receives a voltage for programming the OTP memory cell, wherein the level of the voltage can be adjusted according to a feedback current from the source line of the OTP memory cell.

7. A structure comprising an OTP memory cell, said structure comprising:
a N-type substrate, wherein a P-Well region is formed in the N-type substrate, wherein a first N+ region, a second N+ region, a third P+ region are formed in the P-Well region and a gate is formed over the P-Well region so that the first N+ region and the second N+ region and the gate form a N-Channel field-effect transistor (FET); and
a first fuse element, disposed on the N-type substrate, wherein one terminal of the first fuse element is electrically connected to the first N+ region so as to form the OTP memory cell, wherein the other terminal of the first fuse element is electrically connected to a bit line of the OTP memory cell, and the second N+ region and the third P+ region are electrically connected to a source line (SL) of the OTP memory cell, wherein the source line (SL) of the OTP memory cell is electrically connected to a power supply when programming the OTP memory cell so as to enable a current to flow from the third P+ region to the first N+ region via a parasitic diode in the P-Well region, and the source line (SL) of the OTP memory cell is electrically connected to a ground when performing a read operation on the OTP memory cell.

8. The circuit according to claim 7, wherein the fuse element is a fuse.

9. The circuit according to claim 7, wherein the fuse element is an antifuse.

10. The circuit according to claim 7, wherein the OTP memory cell is made by a CMOS process.

11. The circuit according to claim 7, wherein the source line of the OTP memory cell receives a current for programming the OTP memory cell, wherein the amount of the current can be adjusted according to a feedback voltage from the OTP memory cell.

12. The circuit according to claim 7, wherein the source line of the OTP memory cell receives a voltage for programming the OTP memory cell, wherein the level of the voltage can be adjusted according to a feedback current from the bit line of the OTP memory cell.

13. A structure comprising a programmable resistive memory cell, said structure comprising:
a P-type substrate, wherein an N-Well region is formed in the P-type substrate, wherein a first P+ region, a second P+ region, a third N+ region are formed in the N-Well region and a gate is formed over the N-Well region so that the first P+ region and the second P+ region and the gate form a P-channel field-effect transistor (FET); and
a first programmable resistive element, disposed on the P-type substrate, wherein one terminal of the first programmable resistive element is electrically connected to the first P+ region so as to form the programmable resistive memory cell, wherein the other terminal of the first programmable resistive element is electrically connected to a bit line of the programmable resistive memory cell, and the second P+ region and the third N+ region are electrically connected to a source line (SL) of the programmable resistive memory cell, wherein the source line (SL) of the programmable resistive memory cell is electrically connected to a ground when programming the programmable resistive memory cell so as to enable a current to flow from the first P+ region to the third N+ region via a parasitic diode in the N-Well region, and the source line (SL) of the programmable resistive memory cell is electrically connected to a power supply when performing a read operation on the programmable resistive memory cell.

14. The circuit according to claim 13, wherein the programmable resistive memory cell is made by a CMOS process.

15. The circuit according to claim 13, wherein the bit line of the programmable resistive memory cell receives a current for programming the programmable resistive memory cell, wherein the amount of the current can be adjusted according to a feedback voltage from the programmable resistive memory cell.

16. The circuit according to claim 13, wherein the bit line of the programmable resistive memory cell receives a voltage for programming the programmable resistive memory cell, wherein the level of the voltage can be adjusted according to a feedback current from the source line of the programmable resistive memory cell.
